(19) United States
(12) Patent Application Publication
(10) Pub. No.: US 2005/0194678 A1
(43) Pub. Date: Sep. 8, 2005

(54) Bonding pad structure, display panel and bonding pad array structure using the same and manufacturing method thereof

(75) Inventor: Meng-Ju Chuang, Hsinchu City (TW)

Correspondence Address: LIU & LIU, 444 S. FLOWER STREET, SUITE 1750, LOS ANGELES, CA, 90071, US

(73) Assignee: Toppoly Optoelectronics Corp.

(21) Appl. No.: 11/021,836

(22) Filed: Dec. 22, 2004

(30) Foreign Application Priority Data
Mar. 5, 2004 (TW) 93105818

(51) Int. Cl. H01L 23/495

(52) U.S. Cl. 257/734

(57) ABSTRACT

A bonding pad structure is provided. The bonding pad is suitable for, such as display device including liquid crystal panel, printed circuit board (PCB) or other loader requiring a plurality of pins requiring high precision of bonding. The bonding pad structure includes a plurality of stacked pin layers and at least one dielectric layer disposed between every two of the pin layers. The terminal of the pin layers is not covered by the dielectric layer. In addition, a bonding pad array structure of the invention may be provided by arranging the bonding pad structure in a staggered manner over a loader or a substrate. Moreover, the bonding pad structure and the bonding pad array structure described above may be applied in display panels.

### CROSS-REFERENCE TO RELATED APPLICATION

This application claims the priority benefit of Taiwan application serial no. 93105818, filed on Mar. 5, 2004

### BACKGROUND OF THE INVENTION

1. Field of the Invention

The present invention generally relates to a bonding pad structure and a manufacturing method thereof. More particularly, the present invention relates to a bonding pad array structure and a panel structure using the bonding pad structure described above, and a manufacturing method thereof.

2. Description of Related Art

In recent years, the design of the layout of the pixel control circuit is extremely limited by the size of the display panel directly, especially in a small size portable electronic device. Therefore, the design of the layout of the circuit of the display panel, including the bonding pads for electrically coupling to external circuits, is an important issue for manufacturing the display panel.

FIG. 1 is a drawing schematically illustrating the structure of a conventional bonding pad and a connection with an external circuits. FIG. 2A is a drawing schematically illustrating a layout structure of a conventional bonding pad array. FIG. 2B is a drawing schematically illustrating a layout structure of another conventional bonding pad array. Referring to FIG. 1, FIG. 2A and FIG. 2B, the conventional bonding pad 100 is disposed on the loader 102 and the loader 200 respectively. In addition, the bonding pad 100 is internally connected to the main circuit 104 and 204, wherein the connection lines are disposed inside the loader 102 and 200 respectively. Referring to FIG. 1, the external circuits 112 may be electrically connected to the bonding pad 100 by the connection wires 106 respectively, wherein each connection wire 106 is bonded on the bonding pad 100 by a lead 108 respectively. For example, in a conventional liquid crystal display panel, the bonding pad 100 is generally disposed on the non-display area (e.g., the loader 102 or 200) of the display panel and is electrically connected to the input/output terminal (I/O terminal) of the driving chip (e.g., the external circuits 112). Alternatively, the bonding pad 100 may also be electrically connected to the flexible printed circuit (FPC) via the anisotropic conductive film (ACF) (e.g., a sheet of connection wires 106 as shown in FIG. 1). As shown in FIG. 2A, the bonding pads 100 in the bonding pad array 202 are arranged in a row and separated from each other by a spacing P. The distance between the first bonding pad and the last bonding pad, i.e., the extent of the lateral coverage D of the pad array 202, is dependent in part on the number of bonding pads 100 and the interval P between two adjacent bonding pads 100.

If the number of bonding pads in the bonding pad array 202 is too large, the precision of the bonding between the bonding pad and leads of the chip (e.g., the leads 108 as shown in FIG. 1) (or the flexible printed circuit, e.g., a sheet of connection wires 106 as shown in FIG. 1) will be influenced by the accumulated tolerance of the interval P. Furthermore, as the resolution of the display panel is increased, the distribution range D of the bonding pad array 202 will extend over a large area of the border and could well extend to close to the length of the border of the display panel. For high resolution panels, even more border space is needed, which affects the size of the panel. In the past, certain efforts have been made to minimize the extent of D. However, in order to maintain the reliability of the bonding between the bonding pads 100 and the driving chip (or the flexible printed circuit), the interval P between two adjacent bonding pads 100 must be maintained in a certain minimum distance. Further, the bonding pad needs to have a certain minimum size for effective bonding to the leads of the chip. Therefore, there is a limit to minimize the distribution range D of the bonding pad array 202.

Referring to FIG. 2B, in another conventional technology, the bonding pads 100 are arranged in a staggered manner to be a multi-row bonding pad array 202 to minimize the distribution range D′ of the bonding pad array 202. In comparison with FIG. 2A, the distance D′ between the first bonding pad and the last bonding pad are minimized drastically.

Due to the increasing demand to develop smaller liquid crystal panels for deployment in small electronic devices, the size of the loader 200 will also be reduced. Further, with increasing demand for higher resolution panels, Therefore, the design of layout of the bonding pads is still a serious problem.

### SUMMARY OF THE INVENTION

Therefore, the present invention is directed to provide a novel bonding pad structure and a bonding pad array structure, in which the pin terminals are arranged to be at more than one layer level. In addition, the present invention is directed to provide a display panel having the bonding pad structure and a bonding pad array structure described above. Moreover, the present invention is directed to provide a manufacturing method of bonding pad. Thus, the density of the layout of the bonding pad structure is enhanced drastically, the distance between the first bonding pad and the last bonding pad is shortened obviously and the precision of bonding is excellent even the numbers of the pads are large.

Hereinafter, in the present invention, a bonding pad structure is provided for disposed on a substrate such as a liquid crystal panel, a printed circuit board (PCB) or other loader. The bonding pad structure comprise, for example but not limited to, a plurality of stacked pin layers and at least one dielectric or insulating layer disposed between adjacent pin layers. In one embodiment of the invention, part of the lower pin layer form terminals, which are, for example but not limited to, not covered by the dielectric layer, and the terminals of each pin layer are mutually separated.

Hereinafter, in the present invention, a bonding pad array structure is provided. The bonding pad array structure comprises, for example but not limited to, a plurality of bonding pad structures described above. In one embodiment of the invention, the bonding pad structure is arranged in a row or arranged into a plurality of staggered rows.

In one embodiment of the present invention, the bonding pad structure comprises, for example but not limited to, two pin layers including, for example, a first pin layer and a second pin layer. Therefore, only one dielectric layer is necessary to be disposed between the first pin layer and the second pin layer. The dielectric layer is disposed over the first pin layer, and the terminal of the first pin layer is exposed. The second pin layer is disposed over the dielectric layer and is electrically insulated to the first pin layer. In addition, the terminal of the first pin layer and the terminal of the second pin layer are mutually separated.

In one embodiment of the present invention, the dielectric layer is only disposed over the first pin layer. Alternatively, the dielectric layer may be disposed over a portion of the substrate apart from the first pin layer and covers the first pin layer, wherein only the terminal of the first pin layer is exposed.

Hereinafter, in the present invention, a display panel is provided. The display panel may comprise an array comprising a plurality of display elements, a control circuit for controlling the array of the display elements, and a bonding pad structure. The bonding pad structure may comprise, for example, a plurality of stacked pin layers and at least one dielectric layer, disposed between adjacent pin layers.

Hereinafter, in the present invention, an electronic device is provided. The electronic device may comprise, for example, a display panel and a control device. The display panel may comprise an array of display elements, a circuit controlling the array of display elements and a bonding pad structure. The bonding pad structure may comprise a plurality of stacked pin layers and at least one dielectric layer, disposed between adjacent pin layers. The control device may be adopted for receiving an image data and controlling the operation of the display panel in accordance with the image data.

Hereinafter, in the present invention, a method of manufacturing the bonding pad is provided. The method comprises the following steps. First, a substrate is provided. Then, a staggered multilayer bonding pad structure is formed over the substrate by forming at least two pin layers and at least one dielectric layer between every two pin layers.

Accordingly, since the bonding pad structure of the present invention comprises a plurality of stacked pin layers, the density of the layout of the bonding pad structure is increased drastically. Thus, the distribution range of the bonding pad array, i.e., the distance between the first bonding pad and the last bonding pad is reduced drastically. In addition, the precision of bonding is enhanced drastically.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of this invention, and are incorporated in and constitute a part of this specification. The following drawings illustrate embodiments of this invention and, together with the description, serve to explain the principles of the invention.

FIG. 1 is a drawing schematically illustrating the structure of a conventional bonding pad and a connection with an external circuits.

FIG. 2A is a drawing schematically illustrating the structure of a conventional bonding pad array.

FIG. 2B is a drawing schematically illustrating the structure of another conventional bonding pad array.

FIG. 3 and FIG. 4 are drawings schematically illustrating the structure of a bonding pad according to one embodiment of the present invention.

FIG. 5A and FIG. 5B are drawings schematically illustrating the bonding pad array constructed by the bonding pads shown in FIG. 3 or FIG. 4.

FIG. 6 and FIG. 7 are drawings schematically illustrating the structure of a bonding pad according to one embodiment of the present invention.

FIG. 8 is a drawing schematically illustrating the structure of a display panel having a bonding pad according to one embodiment of the present invention.

FIG. 9 is a drawing schematically illustrating the structure of an electronic device according to one embodiment of the present invention.

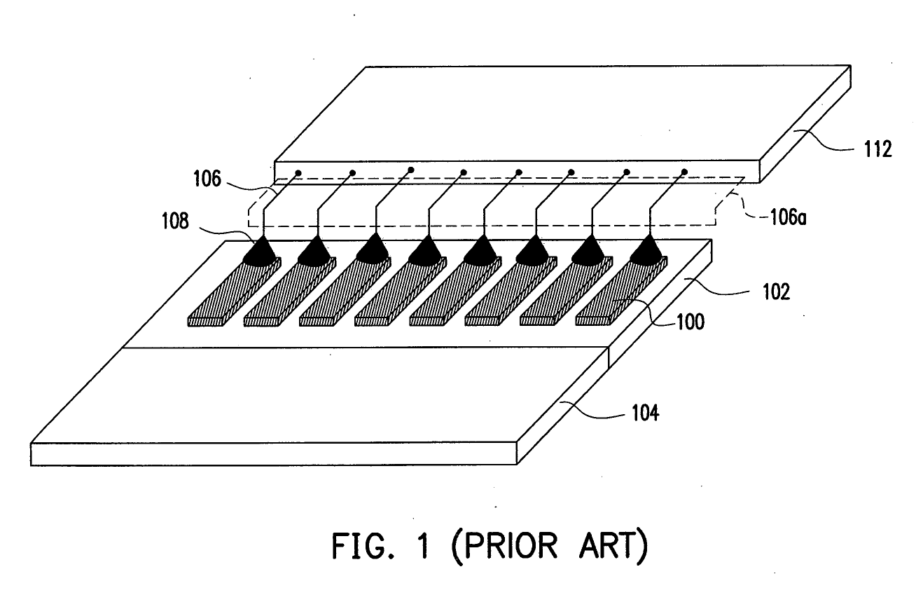

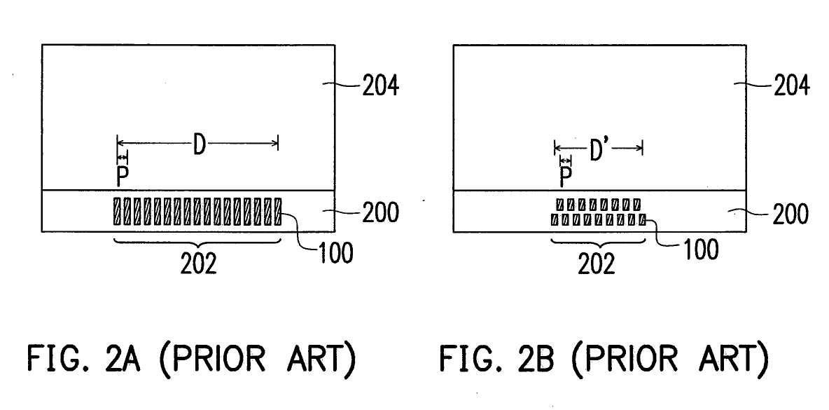

### DESCRIPTION OF THE ILLUSTRATED EMBODIMENTS

The present invention now will be described more fully hereinafter with reference to the accompanying drawings, in which illustrated embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

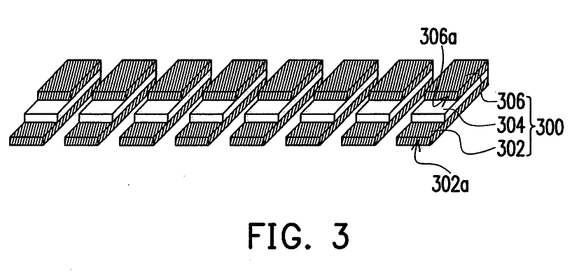

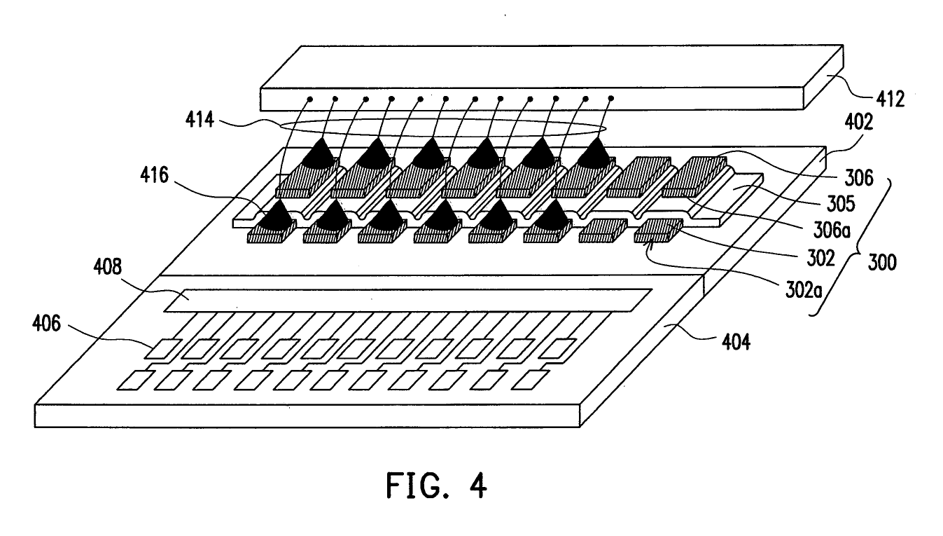

FIG. 3 is a drawing schematically illustrating the structure of a bonding pad according to one embodiment of the present invention. FIG. 4 is a drawing schematically illustrating the structure of a bonding pad and a connection with an external circuits according to one embodiment of the present invention. Referring to FIG. 3 and FIG. 4, the bonding pad 300 comprises, for example but not limited to, a first pin layer 302, a dielectric layer 304 and a second pin layer 306. The dielectric layer 304 is disposed over the first pin layer 302 and expose the terminal 302a of the first pin layer 302. The second pin layer 306 is disposed over the dielectric layer 304, wherein the second pin layer 306 and the first pin layer 302 are electrically insulated mutually. In addition, the terminal 302a of the first pin layer 302 is, for example, separated from the terminal 306a of the second pin layer 306 by a distance. Referring to FIG. 4, the bonding pad 300 may be disposed on a loader 402. In one embodiment of the present invention, the main frame 404 may comprise a plurality of display elements 406 (e.g., pixels) thereon, wherein the display elements are connected to a control circuit 408. In addition, the bonding pad 300 is internally connected to the control circuit 408 of the main frame 404, wherein the connection lines may be disposed inside the loader 402 respectively. Furthermore, the bonding pad 300 may be connected to external circuits 412 by connection wires 414, wherein the connection wires 414 are bonded on the bonding pad 300 by leads 416. It should be noted that, FIG. 4 is an exemplary embodiment and can not be used to limit the scope of the present invention.

Referring to FIG. 3 and FIG. 4, when the pin layer are divided into two layers such as the first pin layer 302 and the second pin layer 306, only one dielectric layer 304 is necessary to be disposed between the first pin layer 302 and the second pin layer 306. As shown in FIG. 3, the dielectric layer 304 is disposed over the first pin layer 302 and expose the terminal 302a of the first pin layer 302. In addition, as shown in FIG. 4, the dielectric layer 305 is disposed over the substrate apart from the first pin layer 302 and covers the first pin layer 302, wherein only the terminal 302a of the first pin layer 302 is exposed.

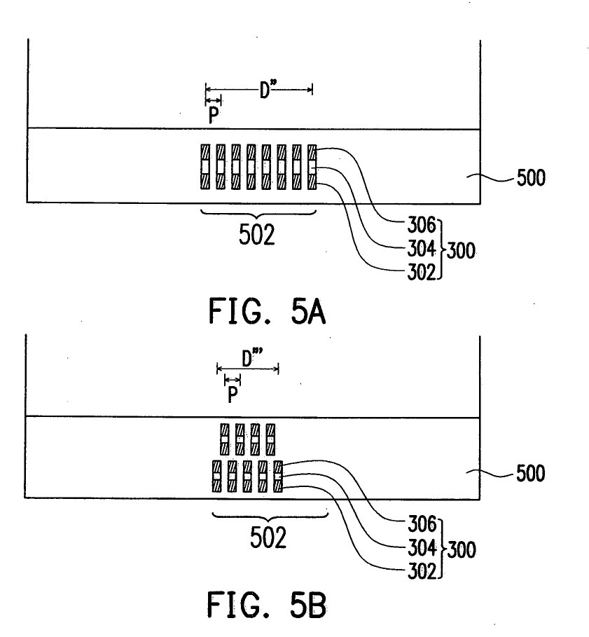

FIG. 5A and FIG. 5B are drawings schematically illustrating the bonding pad array constructed by the bonding pads shown in FIG. 3 or FIG. 4. Referring to FIG. 5A, the bonding pads 300 are disposed over the loader 500. For example, in a liquid crystal display panel, the bonding pads 300 are generally disposed on the non-display area of the display panel, and electrically connected to the input/output terminal of the driving chip. Alternatively, the bonding pads 300 are electrically connected to the flexible printed circuit (FPC) via the anisotropic conductive film (ACF). As shown in FIG. 5A, the bonding pads 300 in the bonding pad array 502 are arranged in a row and separated from each other by a certain interval P. The bonding pads 300 comprises, for example, a two-layer structure having a first pin layer 302, a dielectric layer 304 and a second pin layer 306.

Since in the embodiment described above, the bonding pad 300 is designed as a two-layer structure, thus two times of contacts are disposed in the same layout area (or distance) in comparison with the conventional design. Therefore, the distribution range of the bonding pad array 502, i.e., the distance D″ between the first bonding pad to the last bonding pad is reduced drastically.

Thereafter, referring to FIG. 5B, the distribution range of the bonding pad array 502 is further reduced by arranging the bonding pad 300 in a staggered multilayer structure, thus the precision of bonding is enhanced drastically. It is noted that, in the present embodiment, the distribution range of the bonding pad array 502, i.e., the distance D′″ between the first bonding pad to the last bonding pad is further reduced.

Accordingly, the bonding pad array 502 of the present invention can be applied in a variety of display device requiring high precision of circuit bonding of pins, such as amorphous silicon (a-Si) thin film transistor (TFT) liquid crystal display (LCD) (a-Si TFT LCD) or low temperature polysilicon (LTPS) TFT LCD or organic/polymer light emitting device(OLED/PLED). Since the array structure of the TFT is manufactured by using a plurality of masks, the bonding pad array 502 of the present invention can be incorporated with the TFT array structure by modifying the mask slightly to fit the manufacturing process. No external mask and process is required, thus the process time and cost is not increased.

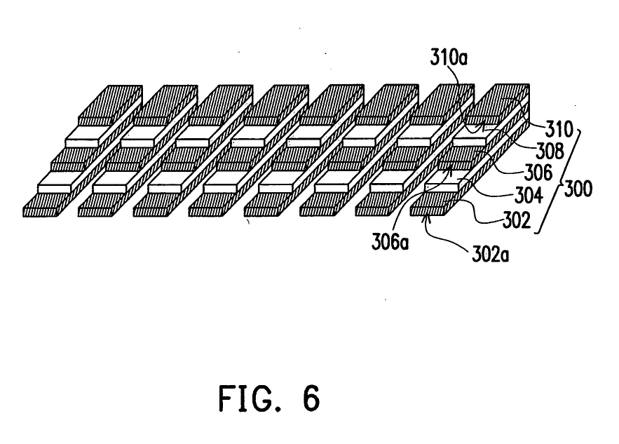

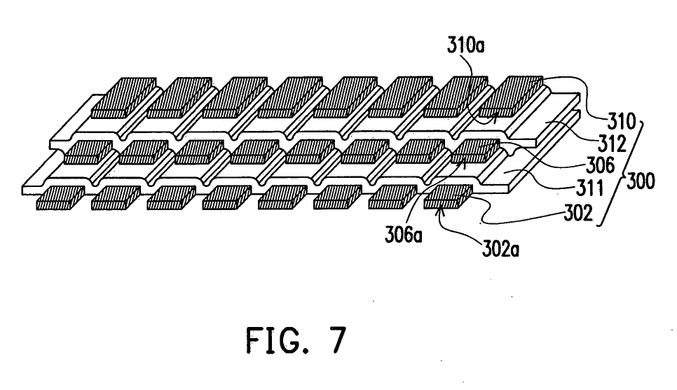

FIG. 6 and FIG. 7 are drawings schematically illustrating the structure of a bonding pad according to one embodiment of the present invention. It is noted that the layer structure of the pin layer of FIG. 6 and FIG. 7 is different to that of the FIG. 3 and FIG. 4. Referring to FIG. 6 and FIG. 7, the bonding pad structure 300 comprises, for example but not limited to, a first pin layer 302, a dielectric layer 304, a second pin layer 306, a dielectric layer 308 and a third pin layer 310. The dielectric layer 304 is disposed between the first pin layer 302 and the second pin layer 306, and the dielectric layer 308 are disposed between the second pin layer 306 and the third pin layer 310. Thus, the pins are divided into three layers, and the terminals 302a, 306a and 310a of the first pin layer 302, the second pin layer 306 and the third pin layer 310 are not covered by the dielectric layers 304 and 308. In another embodiment of the invention, the terminals 302a, 306a and 310a of the first pin layer 302, the second pin layer 306 and the third pin layer 310 are, for example but not limited to, separated from each other by a distance.

Referring to FIG. 6, the dielectric layer 304 is only disposed over the first pin layer 302 and the terminals 302a of the first pin layer 302 are exposed. The dielectric layer 308 is only disposed over the second pin layer 306 and the terminals 306a of the second pin layer 306 are exposed. The third pin layer 310 is disposed over the dielectric layer 308.

In addition, Referring to FIG. 7, the dielectric layer 311 is disposed over a portion of the substrate apart from the first pin layer 302 and covers the first pin layer 302, wherein only the terminals 302a of the first pin layer 302 are exposed. The dielectric layer 312 is disposed over a portion of the dielectric layer 311 and covers the second pin layer 306, wherein only the terminals 306a of the second pin layer 306 are exposed. The third pin layer 310 is disposed over the dielectric layer 312.

In the embodiment of the invention described above, the bonding pad (or bonding array) structure, for example but not limited to, is arranged in a staggered manner over the substrate. Thus, a staggered multilayer bonding pad (array) structure including at least two pin layers and at least one dielectric layer interlaced in the pin layers is formed.

In the embodiment of the present invention, a two-layer and a three-layer bonding pad structure is illustrated as examples, however, the number and the structure of the pin layers of the bonding pad structure of the present invention is not limited to the embodiments. It is noted that, in another embodiment of the present invention, the bonding pad may be constructed by N pin layers and (N-1) dielectric layers, wherein N is larger than or equal to 2.

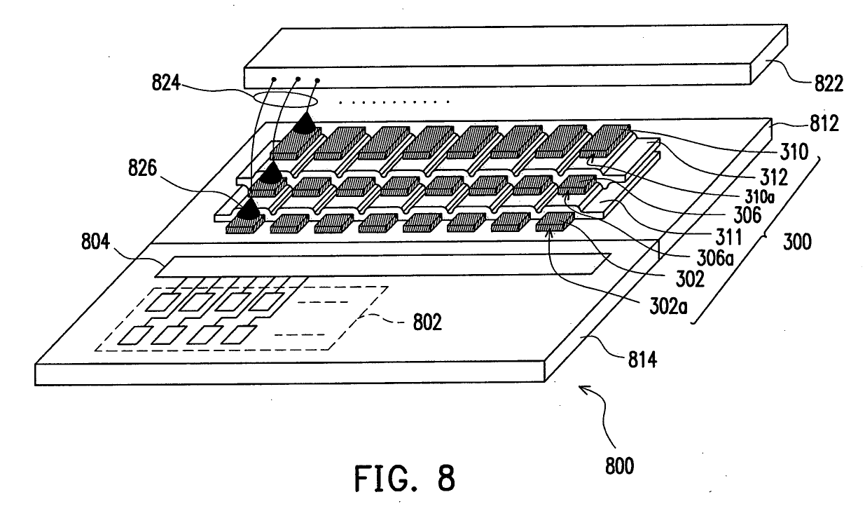

FIG. 8 is a drawing schematically illustrating the structure of a display panel having a bonding pad according to one embodiment of the present invention. Referring to FIG. 8, a display panel 800 may comprise an array of display elements 802, a control circuit 804 for controlling the array of display elements 802, and a bonding pad structure 300. The array of display elements 802 may comprise, for example, the pixels of a display device. The control circuit 804 may be, for example, connected to the array of display elements 802. The bonding pad structure 300 may comprise, for example, a plurality of stacked pin layers 302, 306, 310, and at least one dielectric layer such as dielectric layers 311 and 312 may be disposed between adjacent pin layers. The bonding pad structure 300 may be disposed on a load layer 812, and the array of display elements 802 and the control circuit 804 may be disposed on a main frame 814. In addition, the bonding pad structure 300 of the present invention can not be limited to the drawing shown in FIG. 8 but may be any one applicable bonding pad structure of the present invention.

Referring to FIG. 8, each bonding pad of the bonding pad structure 300 may be connected to an external circuits 822 by, for example, a set of connection wires 824, wherein each connection wire 824 may be bonded on the bonding pad by a lead 826 respectively.

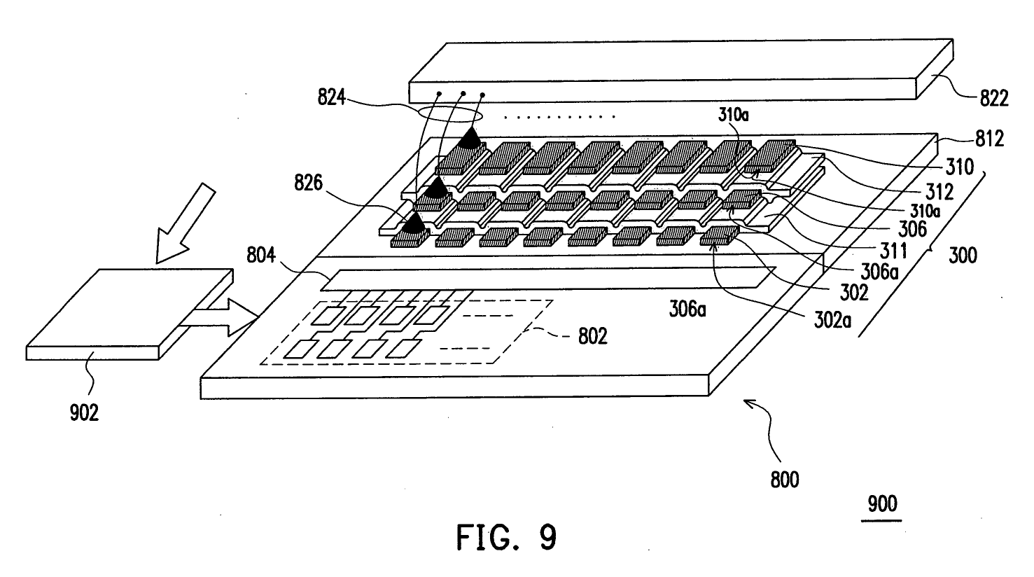

FIG. 9 is a drawing schematically illustrating the structure of an electronic device according to one embodiment of the present invention. As shown in FIG. 9, the electronic device 900 may comprise, for example, a display panel 800 as shown in FIG. 8 and a control device 902 for receiving an image data and controlling the operation of the display panel 800 in accordance with the image data.

Accordingly, in the bonding pad structure of the present invention, all of the pins are allocated in at least two or more layers, thus the density of the layout of the bonding pad structure is enhanced drastically. In addition, the distance between the first bonding pad and the last bonding pad is shortened drastically. Moreover, the total accumulated tolerance of the distance of the bonding pad are also reduce drastically due to the distance between the first bonding pad and the last bonding pad is shortened. Thus, the precision of bonding is enhanced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A bonding pad structure which is disposed on a substrate, comprising:
a plurality of stacked pin layers; and
at least one dielectric layer, disposed between adjacent pin layers.

2. The bonding pad structure of claim 1, wherein each of the pin layers has a terminal and each of the terminals are mutually separated.

3. The bonding pad structure of claim 1, wherein the pin layers comprises:
a first pin layer, wherein the dielectric layer is disposed over the first pin layer and the terminal of the first pin layer is exposed; and
a second pin layer, disposed over the dielectric layer, wherein the second pin layer and the first pin layer are electrically insulated.

4. The bonding pad structure of claim 3, wherein the terminal of the first pin layer and the terminal of the second pin layer are mutually separated.

5. The bonding pad structure of claim 3, wherein the dielectric layer is disposed over the substrate.

6. A bonding pad array structure comprising a plurality of the bonding pad structures of claim 1.

7. The bonding pad array structure of claim 6, wherein the terminals are mutually separated.

8. The bonding pad array structure of claim 6, wherein the bonding pad structures are array arranged.

9. The bonding pad array structure of claim 6, wherein the bonding pad structures are arranged into a plurality of staggered rows.

10. The bonding pad array structure of claim 6, wherein the pin layers comprises:
a first pin layer, wherein the dielectric layer is disposed over the first pin layer and a terminal of the first pin layer is exposed; and
a second pin layer, disposed over the dielectric layer, wherein the second pin layer and the first pin layer are electrically insulated.

11. The bonding pad array structure of claim 10, wherein the terminal of the first pin layer and the terminal of the second pin layer are mutually separated.

12. The bonding pad structure of claim 10, wherein the dielectric layer is disposed over the substrate.

13. The bonding pad structure of claim 1, wherein the bonding pad structure may be adopted for a circuit supported on a substrate, wherein the pin layers are electrically coupled to a different part of the circuit, and each terminating in an exposed terminal.

14. An electronic device, comprising:
a display panel, comprising:
an array comprising a plurality of display elements;
a control circuit for controlling the array of the display elements; and
a bonding pad structure, comprising:
a plurality of stacked pin layers; and
at least one dielectric layer, disposed between adjacent pin layers; and
a control device for receiving an image data and controlling the operation of the display panel in accordance with the image data.

15. A method of manufacturing a bonding pad, comprising:
providing a substrate;
forming a first pin layer over the substrate;
forming a dielectric layer over the first pin layer; and
forming a second pin layer over the dielectric layer;
wherein both the first pin layer and the second pin layer terminate in exposed terminals.

16. The method of claim 15, wherein the first pin layer comprises a plurality of pins electrically insulated from each other.

17. The method of claim 15, wherein the second pin layer comprises a plurality of pins electrically insulated from each other.

18. The method of claim 15, wherein the terminal of the first pin layer and the terminal of the second pin layer are mutually separated.
